(19) United States
(12) Patent Application Publication
(10) Pub. No.: US 2019/0019968 A1
(43) Pub. Date: Jan. 17, 2019

(54) COLLIMATED LIGHT SOURCE, MANUFACTURING METHOD THEREOF AND DISPLAY DEVICE

(71) Applicant: BOE TECHNOLOGY GROUP CO., LTD.

(72) Inventors: Xiaolong HE, Beijing (CN); Yingtao WANG, Beijing (CN); Feng GUAN, Beijing (CN); Jikai YAO, Beijing (CN)

(73) Assignees: BOE TECHNOLOGY GROUP CO., LTD., Beijing (CN); BOE TECHNOLOGY GROUP CO., LTD., Beijing (CN)

(21) Appl. No.: 15/749,761

(22) PCT Filed: Jun. 29, 2017
(86) PCT No.: PCT/CN2017/090741

§ 371 Date: Feb. 1, 2018

(30) Foreign Application Priority Data
Sep. 5, 2016 (CN) 201610802228.1

(51) Int. Cl. H01L 51/50; H01L 51/52; H01L 51/56; G02F 1/1335; G02B 27/30

(52) U.S. Cl. CPC H01L 51/504; H01L 51/5275; H01L 51/56; G02F 2001/133607; G02F 1/133606; G02B 27/30; H01L 51/5271

(57) ABSTRACT

The embodiments of the present disclosure disclose a collimated light source, a manufacturing method thereof and a display device. The collimated light source includes a substrate, a film layer with a plurality of concave microstructures on the substrate, a reflective layer on the film layer, and a plurality of light-emitting parts corresponding to the concave microstructures one-to-one. Each of the light-emitting parts is located at a focal point of a corresponding concave microstructure. According to the embodiments of the present disclosure, the light emitted from each light-emitting part is reflected by the reflective layer on the corresponding concave microstructure and then exits in parallel light from a side of the reflective layer facing away from the substrate.

### RELATED APPLICATIONS

The present application is the U.S. national phase entry of the international application PCT/CN2017/090741, with an international filing date of Jun. 29, 2017, which claims the benefit of Chinese Patent Application No. 201610802228.1, filed on Sep. 5, 2016, the entire disclosures of which are incorporated herein by reference.

### TECHNICAL FIELD

The present disclosure relates to the field of display technology, in particular to a collimated light source, a manufacturing method thereof and a display device.

### BACKGROUND

Liquid crystal display (LCD) devices have the advantages of high display quality, no electromagnetic radiation and wide applications, and are currently important display devices. In the existing liquid crystal display devices, white light is generally converted into three-color light of red (R), green (G) and blue (B) by using a color film layer. A light energy loss occurs in the conversion process, resulting in low light extraction efficiency of the liquid crystal display device. In order to ensure a high display brightness for the liquid crystal display device, the power consumption of liquid crystal display device will undoubtedly increase.

At present, the color separation technology can directly separate the collimated light into the RGB three-color light, and the color separation process has almost no loss of light energy. If the color separation technology is applied to the liquid crystal display device, the arrangement of the color film layer in the liquid crystal display device can be omitted, so as to reduce the light energy loss and further improve the light extraction efficiency of the liquid crystal display device. Accordingly, the power consumption of the display device can also be reduced.

### SUMMARY

To this end, the embodiments of the disclosure provide a collimated light source, a manufacturing method thereof and a display device for providing a collimated backlight for a liquid crystal display device.

An embodiment of the present disclosure provides a collimated light source. The collimated light source includes a substrate, a film layer with a plurality of concave microstructures located on the substrate, a reflective layer located on the film layer, and a plurality of light-emitting parts corresponding to the concave microstructures one-to-one; each of the light-emitting parts is located at a focal point of a corresponding concave microstructure.

According to the embodiments of the present disclosure, the light emitted from each light-emitting part is reflected by the reflective layer on the corresponding concave microstructure and then exits in parallel light from a side of the reflective layer facing away from the substrate. The collimated light source can be used to provide a collimated backlight for a display panel, and a color separation technology can be used to display a color image even when the color film layer is omitted from the display panel, so as to reduce the light energy loss of the display panel and further improve the light extraction efficiency of the liquid crystal display panel. Accordingly, the power consumption of the display panel can also be reduced.

In a possible implementation, in the above-described collimated light source provided by an embodiment of the present disclosure, the surface of each of the concave microstructures is a parabolic surface or a spherical surface.

In a possible implementation, in the above-described collimated light source provided by an embodiment of the present disclosure, a depth of each of the concave microstructures ranges from 8 μm to 80 μm, and a diameter of each of the concave microstructures ranges from 20 μm to 150 μm.

In a possible implementation, in the above-described collimated light source provided by an embodiment of the present disclosure, a material of the film layer with the plurality of concave microstructures is a thermosetting resin.

In a possible implementation, in the above-described collimated light source provided by an embodiment of the present disclosure, the collimated light source further includes a planarization layer located between the reflective layer and the film layer where each of the light-emitting parts is located.

In a possible implementation, in the collimated light source provided by an embodiment of the present disclosure, a viscosity of the planarization layer ranges from 0.1×10⁻⁶ mPa·s to 1.5×10⁻⁶ mPa·s.

In a possible implementation, in the above-described collimated light source provided by an embodiment of the present disclosure, a refractive index of the planarization layer ranges from 1.5 to 2.

In a possible implementation, in the above-described collimated light source provided by an embodiment of the present disclosure, a material of the planarization layer includes any one of epoxy resin, acrylic resin and polyimide resin.

In a possible implementation, in the above-described collimated light source provided by an embodiment of the present disclosure, each of the light-emitting parts is an organic electroluminescent structure. The organic electroluminescent structure includes a transparent first electrode, a light-emitting layer and a reflective second electrode, which are sequentially stacked along a direction from the substrate toward the reflective layer.

In a possible implementation, in the above-described collimated light source provided in an embodiment of the present disclosure, an area of the light-emitting layer in each of the organic electroluminescent structures ranges from 2 μm² to 15 μm².

In a possible implementation, in the above-described collimated light source provided by an embodiment of the present disclosure, an area of the second electrode in each of the organic electroluminescent structures ranges from 4 μm² to 20 μm².

In a possible implementation, in the above-described collimated light source provided in an embodiment of the present disclosure, a thickness of the second electrode in each of the organic electroluminescent structures ranges from 100 nm to 500 nm.

In a possible implementation, in the above-described collimated light source provided by an embodiment of the present disclosure, a material of the reflective layer includes any one of aluminum, aluminum neodymium alloy and silver.

In a possible implementation, in the above-described collimated light source provided by an embodiment of the present disclosure, a thickness of the reflective layer ranges from 100 nm to 500 nm.

In a possible implementation, in the above-described collimated light source provided by an embodiment of the present disclosure, the plurality of light-emitting parts are point light sources arranged in an array, and the plurality of concave microstructures are a plurality of recesses arranged in an array. Alternatively, the plurality of light-emitting parts are line light sources arranged parallel to each other, and the plurality of concave microstructures are a plurality of grooves arranged parallel to each other.

An embodiment of the present disclosure further provides a display device. The display device includes a display panel, a backlight module, and a color separation layer between the display panel and the backlight module. The backlight module is the above-described collimated light source provided by an embodiment of the present disclosure.

An embodiment of the present disclosure further provides a method for manufacturing a collimated light source.

The method includes: forming a film layer with a plurality of concave microstructures on a substrate; forming a reflective layer on the substrate on which the film layer is formed; and forming a plurality of light-emitting parts corresponding to the concave microstructures one-to-one on the substrate on which the reflective layer is formed. Each of the light-emitting parts is located at a focal point of a corresponding concave microstructure.

In a possible implementation, in the above-described method provided by an embodiment of the present disclosure, the step of forming a film layer with a plurality of concave microstructures includes: forming a film layer on the substrate by using a thermosetting resin material; forming a plurality of concave microstructures by nano-imprinting the film layer; and heat-treating the film layer on which the plurality of concave microstructures is formed.

In a possible implementation, in the above-described method provided by an embodiment of the present disclosure, a heating temperature ranges from 70° C. to 200° C.

In a possible implementation, in the above-described method provided by an embodiment of the present disclosure, after the reflective layer is formed and before each of the light-emitting parts is formed, the method further includes: forming a planarization layer on the substrate on which the reflection layer is formed.

### BRIEF DESCRIPTION OF THE DRAWINGS

In order to more clearly illustrate the technical solutions in embodiments of the disclosure or in the prior art, the appended drawings needed to be used in the description of the embodiments or the prior art will be introduced briefly in the following. Obviously, the drawings in the following description are only some embodiments of the disclosure, and for those of ordinary skills in the art, other drawings may be obtained according to these drawings under the premise of not paying out creative work.

FIG. 1 is a structural schematic diagram of a collimated light source according to an embodiment of the present disclosure;

FIG. 2 is a light path diagram of the collimated light source shown in FIG. 1 emitting collimated light;

FIG. 3 is a structural schematic diagram of a collimated light source according to another embodiment of the present disclosure;

FIG. 4 is a structural schematic diagram of a collimated light source according to yet another embodiment of the present disclosure;

FIG. 5 is a light path diagram of the collimated light source shown in FIG. 4 emitting collimated light;

FIG. 6 is a structural schematic diagram of a collimated light source according to still another embodiment of the present disclosure;

FIG. 7 is a flow chart of a method for manufacturing a collimated light source according to an embodiment of the present disclosure;

FIG. 8a and FIG. 8b are respectively structural schematic diagrams after performing the steps of the method for manufacturing a collimated light source according to an embodiment of the present disclosure;

FIG. 9 is a flow chart of a method for manufacturing a collimated light source according to another embodiment of the present disclosure;

FIG. 10 is a structural schematic diagram of a display device according to an embodiment of the present disclosure;

FIG. 11 is a schematic diagram of a collimated light source according to an embodiment of the present disclosure; and

FIG. 12 is a schematic diagram of a collimated light source according to another embodiment of the present disclosure.

### DESCRIPTION OF REFERENCE SIGNS

1 substrate; 2 film layer with a plurality of concave microstructures; 21 concave microstructure; 3 reflective layer; 4 light-emitting part; 41 first electrode; 42 light-emitting layer; 43 second electrode; 5 planarization layer; 6 encapsulation layer; 100 display panel; 200 backlight module; 300 color separation layer; 401 point light source; 402 recess; 403 line light source; 404 groove; h depth of concave microstructure; d diameter of concave microstructure; H maximum thickness of film layer with a plurality of concave microstructures.

### DETAILED DESCRIPTION OF THE DISCLOSURE

In the following, the technical solutions in the embodiments of the disclosure will be described clearly and completely in connection with the drawings in the embodiments of the disclosure. Obviously, the described embodiments are only part of the embodiments of the disclosure, and not all of the embodiments. Based on the embodiments in the disclosure, all other embodiments obtained by those of ordinary skills in the art under the premise of not paying out creative work pertain to the protection scope of the disclosure.

The shape and thickness of the each layer in the drawings do not reflect the real scale, and are only schematically illustrate the disclosure.

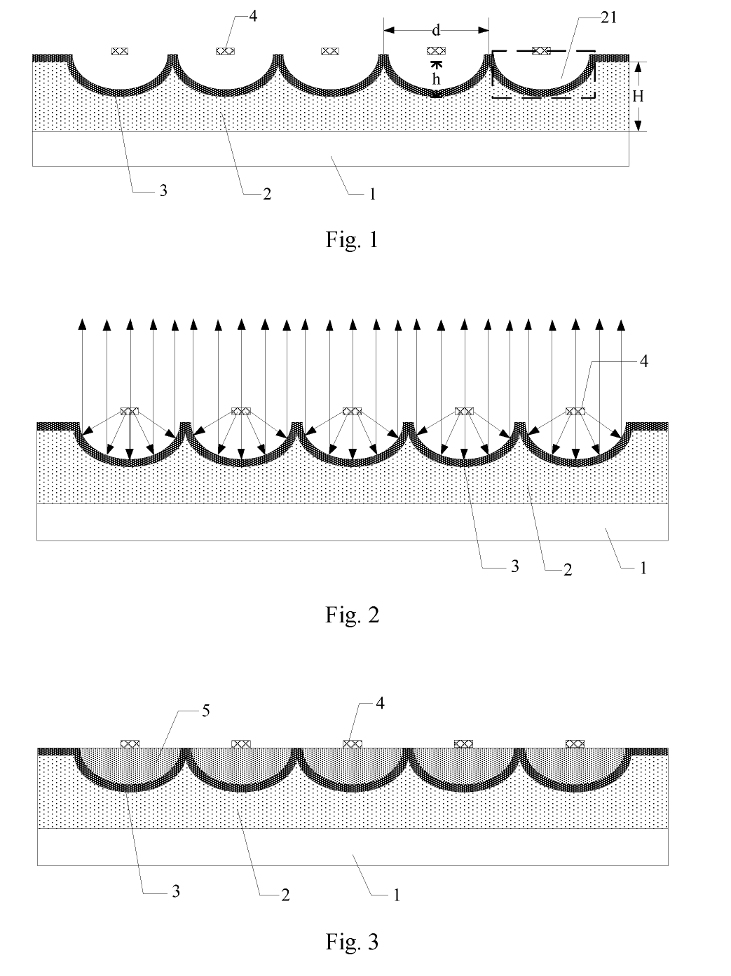

As shown in FIG. 1, a collimated light source provided by an embodiment of the present disclosure includes a substrate 1, a film layer 2 with a plurality of concave microstructures 21 located on the substrate 1, a reflective layer 3 located on the film layer 2, and a plurality of light-emitting parts 4 corresponding to the concave microstructures one-to-one. Each of the light-emitting parts 4 is located at a focal point of a corresponding concave microstructure 21.

As shown in FIG. 2, the light emitted from each light-emitting part 4 is reflected by the reflective layer 3 on the corresponding concave microstructure 21 and then exits in parallel light from a side of the reflective layer 3 facing away from the substrate 1. The collimated light source can be used to provide a collimated backlight for a display panel and a color separation technology can be used to display a color image even when the color film layer is omitted from the display panel, so as to reduce the light energy loss of the display panel and further improve the light extraction efficiency of the liquid crystal display panel. Accordingly, the power consumption of the display panel can also be reduced.

It should be noted that in the above-described collimated light source provided by an embodiment of the present disclosure, light emitted from each light-emitting part is reflected by the reflective layer on the corresponding concave microstructure and then exits in parallel light from a side of the reflective layer facing away from the substrate, and the exit direction of the parallel light can be perpendicular to the substrate. Alternatively, the exit direction of the parallel light can also form an included angle greater than 0° and less than 90° with the substrate, which is not limited herein.

Optionally, in the above-described collimated light source provided by an embodiment of the present disclosure, the surface of each concave microstructure can be a parabolic surface or a spherical surface. In this way, as shown in FIG. 2, after the light emitted from each light-emitting part 4 is reflected by the reflective layer 3 on the corresponding concave microstructure, the light can exit in parallel light perpendicular to the substrate 1 from a side of the reflective layer 3 facing away from the substrate 1.

Of course, in the above-described collimated light source provided by an embodiment of the present disclosure, each concave microstructure is not limited to the structure as shown in FIG. 1, and the surface thereof is not limited to the parabolic surface. Each concave microstructure can also be other structures which enable the light emitted from each light-emitting part to be reflected by the reflective layer on the corresponding concave microstructure and then to exit in parallel light from a side of the reflective layer facing away from the substrate, which is not limited herein.

Optionally, in the above-described collimated light source provided by an embodiment of the present disclosure, in order to ensure that the light emitted from each light-emitting part is well reflected on the surface of the reflective layer on the corresponding concave microstructure, as shown in FIG. 1, a depth h of each concave microstructure can be set in the range of 8 μm to 80 μm and a diameter d of each concave microstructure can be set in the range of 20 μm to 150 μm. It should be noted that, in the above-described collimated light source provided by an embodiment of the present disclosure, in order to form the concave microstructure, as shown in FIG. 1, the maximum thickness H of the film layer 2 with a plurality of concave microstructures needs to be greater than the depth h of each of the concave microstructures. The maximum thickness H of the film layer 2 with a plurality of concave microstructures can be set in the range of 10 μm to 100 μm.

Optionally, in the above-described collimated light source provided by an embodiment of the present disclosure, a material of the film layer with a plurality of concave microstructures can be selected from thermosetting resins. Alternatively, the material of the film layer with a plurality of concave microstructures can also be selected from photo-curable resins, which is not limited herein. Optionally, the material of the film layer with a plurality of concave microstructures is a thermosetting resin. The deformation rate in the heat curing process of the thermosetting resin material is small (which can be controlled under 2%), so that a very high surface accuracy is ensured, thereby ensuring that the collimated light source exit better collimated light. Optionally, the thermosetting resin can be any one of polystyrene resin, polycarbonate resin and silicone resin, which is not limited herein.

Optionally, in the above-described collimated light source provided in an embodiment of the present disclosure, as shown in FIG. 3, the collimated light source can further includes a planarization layer 5 located between the reflective layer 3 and the film layer where each of the light-emitting parts is located; each of the light-emitting parts 4 can be supported at the focal point of the corresponding concave microstructure by the planarization layer 5. Of course, in the above-described collimated light source provided by an embodiment of the present disclosure, other ways of fixing each of the light-emitting parts at the focal point of the corresponding concave microstructure can also be used, which is not limited herein. Those skilled in the art can understand that the planarization layer is transparent to the light emitted by the light-emitting part 4.

Optionally, in the above-described collimated light source provided by an embodiment of the present disclosure, in order to ensure that the planarization layer has good leveling performance so as to ensure that the planarization layer has good flatness, a viscosity of the planarization layer at room temperature can be set in the range of 0.1×10⁻⁶ mPa·s to 1.5×10⁻⁶ mPa·s.

Optionally, in the above-described collimated light source provided by an embodiment of the present disclosure, a refractive index of the planarization layer can be set in the range of 1.5 to 2, so that the light reflected by the reflective layer can be prevented from being irradiated onto the surface of the planarization layer and being totally reflected on the surface of the planarization layer which affects the light extraction efficiency of the collimated light source.

Optionally, in the above-described collimated light source provided by an embodiment of the present disclosure, a material of the planarization layer can be an epoxy resin. Alternatively, the material of the planarization layer can be an acrylic resin. Alternatively, the material of the planarization layer can be a polyimide resin, which is not limited herein. Of course, the material of the planarization layer can also be other materials that satisfy the above-described viscosity range and the above-described refractive index range, which is not limited herein.

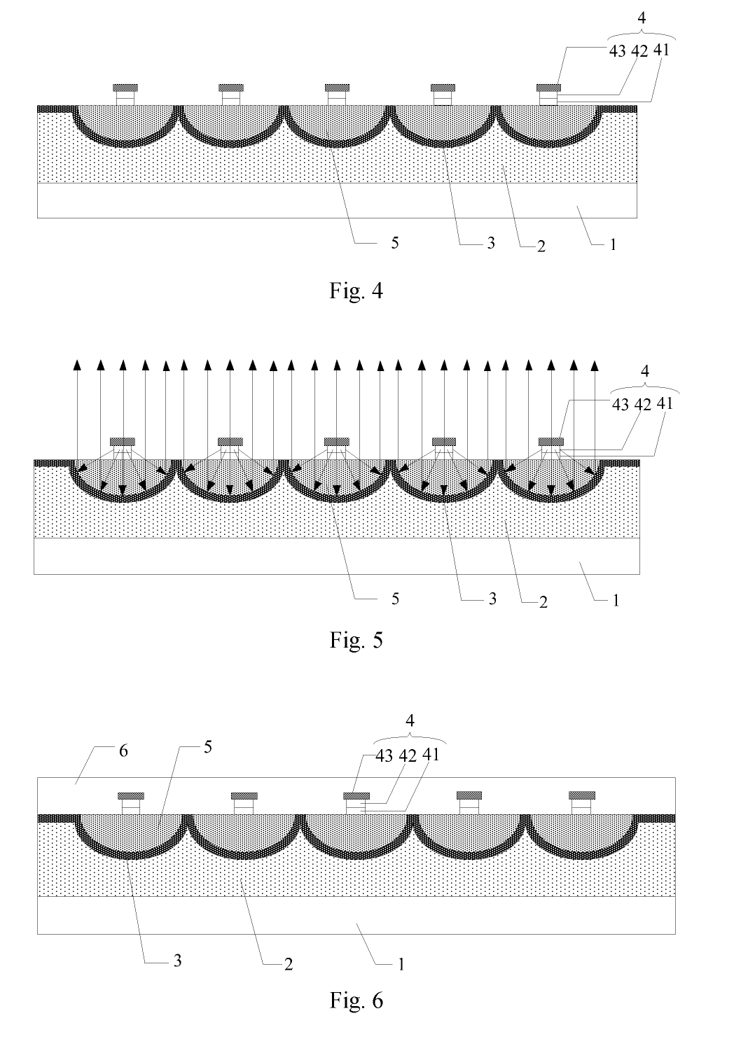

Optionally, in the above-described collimated light source provided by an embodiment of the present disclosure, each light-emitting part can be an organic electroluminescent structure. As shown in FIG. 4, each light-emitting part 4 can include a transparent first electrode 41, a light-emitting layer 42 and a reflective second electrode 43, which are sequentially stacked along a direction from the substrate 1 toward the reflective layer 3. In this way, as shown in FIG. 5, the light emitted by the light-emitting layer 42 in each light-emitting part 4 is reflected by the reflective second electrode 43 to a surface of the reflective layer 3 on the corresponding concave microstructure and then reflected by the surface of the reflective layer 3, and after reflected by the surface of the reflective layer 3 the light is parallel light (i.e., collimated light) exited from a side of the reflective layer 3 facing away from the substrate 1.

Optionally, in order to prevent the organic electroluminescent structures from being damaged by intrusion of water and oxygen in the external environment, as shown in FIG. 6, the above-described collimated light source provided by an embodiment of the present disclosure can further include an encapsulation layer 6 on the film layer where each of the light-emitting parts 4 is located.

Optionally, in the above-described collimated light source provided by an embodiment of the present disclosure, an area of the light-emitting layer in each organic electroluminescent structure can be set in the range of 2 μm² to 15 μm². If the area of the light-emitting layer is too small, the brightness of the collimated light source will be too low (the brightness of the collimated light source should be greater than 500 nits). If the area of the light-emitting layer is too large, it can't be placed as a point light source at the focal point of the concave microstructure.

It should be noted that in the above-described collimated light sources provided by an embodiment of the present disclosure, an area of the reflective second electrode in each organic electroluminescent structure needs to be larger than the area of the light-emitting layer, so as to prevent the light emitted by the light-emitting layer from transmitting through the second electrode and causing loss of light energy. Optionally, the area of the second electrode in each organic electroluminescent structure can be set in the range of 4 μm² to 20 μm². If the area of the second electrode is too small, it will cause light to transmit through the second electrode to cause loss of light energy. If the area of the second electrode is too large, the second electrode will block the exiting collimated light.

Optionally, in the above-described collimated light source provided by an embodiment of the present disclosure, a thickness of the second electrode in each organic electroluminescent structure can be set in the range of 100 nm to 500 nm. If the thickness of the second electrode is too thin, it will cause light to transmit through the second electrode to cause loss of light energy. Optionally, in the above-described collimated light source provided by an embodiment of the present disclosure, the transparent first electrode in each organic electroluminescent structure can be an anode, and the reflective second electrode can be a cathode. Alternatively, the transparent first electrode in each organic electroluminescent structure can be a cathode, and the reflective second electrode can be an anode, which is not limited herein.

In some embodiments, the transparent first electrode in each organic electroluminescent structure is an anode and the reflective second electrode is a cathode. In this case, a material of the transparent first electrode can be a transparent conductive oxide (TCO), such as indium tin oxide (ITO) or indium gallium zinc oxide (IGZO), etc., which is not limited herein. A material of the reflective second electrode can be a metal or an alloy, such as any one of magnesium (Mg), silver (Ag), aluminum (Al), magnesium silver alloy (MgAg), etc., which is not limited herein.

In some embodiments, the transparent first electrode in each organic electroluminescent structure is a cathode and the reflective second electrode is an anode. In this case, the material of the transparent first electrode can be a transparent conductive oxide (TCO), such as indium tin oxide (ITO) or indium gallium zinc oxide (IGZO), etc., which is not limited herein. The reflective second electrode can be a double-layer structure composed of a TCO and a metal. Alternatively, the reflective second electrode can also be a double-layer structure composed of a TCO and an alloy. The TCO can be ITO or IGZO, the metal can be any one of magnesium (Mg), silver (Ag), aluminum (Al), and the alloy can be magnesium silver alloy (MgAg), which is not limited herein.

Optionally, in the above-described collimated light source provided by an embodiment of the present disclosure, a material of the reflective layer can be aluminum (Al). Alternatively, the material of the reflective layer can be aluminum neodymium alloy (AlNd). Alternatively, the material of the reflective layer can be silver (Ag), which is not limited herein. Of course, the material of the reflective layer can also be other materials with high reflectivity, which is not limited herein.

Optionally, in the above-described collimated light source provided by an embodiment of the present disclosure, a thickness of the reflective layer can be set in the range of 100 nm to 500 nm. If the thickness of the reflective layer is too thin, it will cause light to transmit through the reflective layer to cause loss of light energy. If the thickness of the reflective layer is too thick, it will readily cause the problem of detachment between the reflective layer and the film with a plurality of concave microstructures.

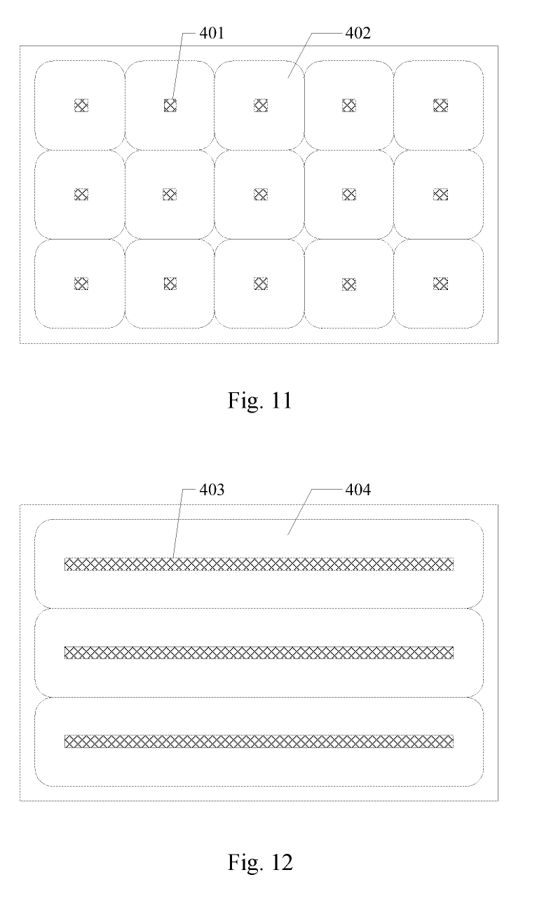

Optionally, in the above-described collimated light source provided by an embodiment of the present disclosure, as shown in FIG. 11, the plurality of light-emitting parts are point light sources 401 arranged in an array, and the plurality of concave microstructures are a plurality of recesses 402 arranged in an array. Alternatively, as shown in FIG. 12, the plurality of light-emitting parts are line light sources 403 arranged parallel to each other, and the plurality of concave microstructures are a plurality of grooves 404 arranged parallel to each other. With such an arrangement, the collimated light source can provide the display panel with collimated light that is uniformly distributed.

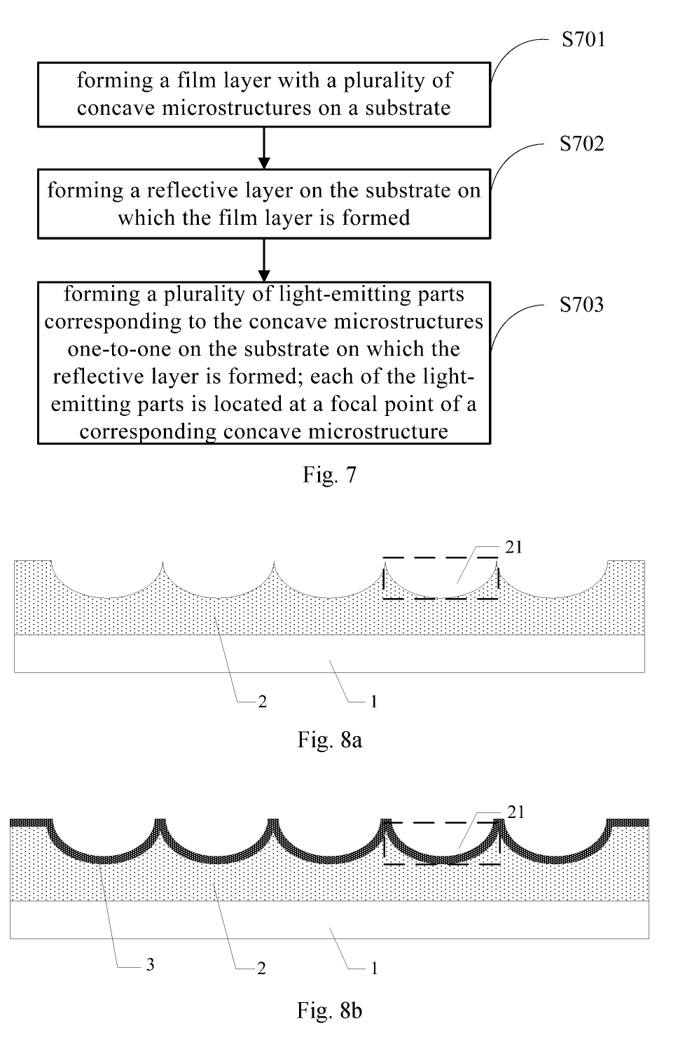

Based on the same concept, an embodiment of the present disclosure further provides a method for manufacturing a collimated light source. As shown in FIG. 7, FIG. 8a and FIG. 8b, the method includes the following steps.

S701: forming a film layer 2 with a plurality of concave microstructures 21 on a substrate 1, as shown in FIG. 8a.

S702: forming a reflective layer 3 on the substrate 1 on which the film layer 2 is formed, as shown in FIG. 8b.

Optionally, the reflective layer can be formed by a sputtering process. Alternatively, the reflective layer can also be formed by a vapor deposition process, which is not limited herein. Optionally, the reflective layer is formed by a vapor deposition process. The surface of the reflective layer thus obtained is more uniform and smooth, so that the reflection effect of the reflective layer can be better and the collimated light can be obtained more easily.

S703: forming a plurality of light-emitting parts 4 corresponding to the concave microstructures 21 one-to-one on the substrate 1 on which the reflective layer is formed; each of the light-emitting parts 4 is located at a focal point of a corresponding concave microstructure.

As a result, the light emitted from each light-emitting part 4 is reflected by the reflective layer 3 on the corresponding concave microstructure and exits in parallel light from a side of the reflective layer 3 facing away from the substrate 1. Then the collimated light source as shown in FIG. 1 is obtained.

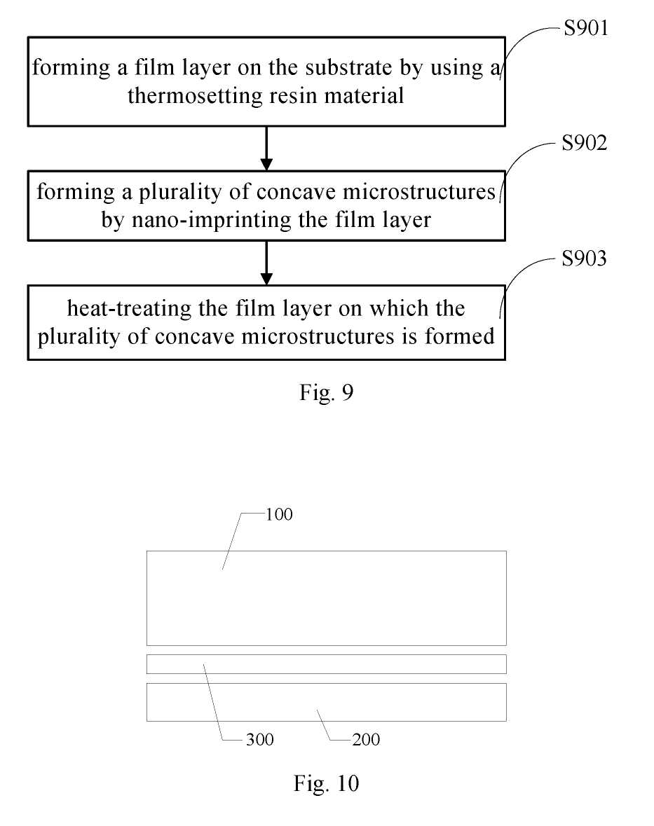

Optionally, when performing the step S701 of forming a film layer with a plurality of concave microstructures in the above-described method provided by an embodiment of the present disclosure, as shown in FIG. 9, the following steps can be included.

S901: forming a film layer on the substrate by using a thermosetting resin material.

Optionally, a thermosetting resin material can be spin-coated on the substrate to form a film layer.

S902, forming a plurality of concave microstructures by nano-imprinting the film layer. Optionally, the film layer can be nano-imprinted with a mold with a complementary pattern of the concave microstructures. It should be noted that the stability of the plurality of concave microstructures formed by the nano-imprint technology is strong, but the formation of the concave microstructures is not limited to the nanoimprint technique. The concave microstructures can also be formed by electron beam lithography, or half-tone mask exposure, etc., which is not limited herein.

S903, heat-treating the film layer on which the plurality of concave microstructures is formed. Optionally, in the above-described method provided by an embodiment of the present disclosure, in order to optimize the curing effect of the thermosetting resin material, the heating temperature of the heat treatment can be set in the range of 70° C. to 200° C.

Optionally, in the above-described method provided in an embodiment of the present disclosure, after performing the step S702 of forming the reflective layer in the above-described method provided in an embodiment of the present disclosure and before performing the step S703 of forming a plurality of light-emitting parts corresponding to the concave microstructures one-to-one in the above-described method provided in an embodiment of the present disclosure, a planarization layer can be further formed on the substrate on which the reflective layer is formed. In this way, when the surface of each concave microstructure is a parabolic surface, each of the light-emitting parts can be supported at the focal point of the corresponding concave microstructure by the planarization layer, so as to ensure that after the light emitted from each light-emitting part is reflected by the reflective layer on the corresponding concave microstructure, the light can exit in parallel light from a side of the reflective layer facing away from the substrate.

Optionally, in the above-described method provided by an embodiment of the present disclosure, when performing the step S703 of forming a plurality of light-emitting parts corresponding to the concave microstructures one-to-one in the above-described method provided in an embodiment of the present disclosure, a plurality of organic electroluminescent structures corresponding to the concave microstructures one-to-one can be formed. In this case, in order to prevent the organic electroluminescent structures from being damaged by intrusion of water and oxygen in the external environment, after a plurality of organic electroluminescent structures are formed, the substrate on which a plurality of organic electroluminescent structures are formed can be encapsulated. For example, an encapsulation layer can be formed on the substrate on which the plurality of organic electroluminescent structures are formed.

Based on the same concept, an embodiment of the present disclosure further provides a display device. As shown in FIG. 10, the display device 100 includes a display panel 100, a backlight module 200, and a color separation layer 300 between the display panel 100 and the backlight module 200. The backlight module 200 is the above-described collimated light source provided by an embodiment of the present disclosure. The color separation layer 300 can be a film layer including at least one step group that can separate the incident light into a plurality of monochromatic light beams (e.g., R, G, B light beams) by using a diffraction effect. Therefore, the color separation layer 300 can directly separate the collimated light emitted from the backlight module 200 into RGB three-color light. In this way, the arrangement of the color film layer in the display panel 100 can be omitted, so as to reduce the light energy loss and further improve the light extraction efficiency of the display device. Experimental data show that the light extraction efficiency of the display device can be increased by about 60%. The display device can be any product or component with a display function, such as a mobile phone, a tablet computer, a television, a display, a notebook computer, a digital photo frame, a navigator, etc. For the implementation of the display device, reference can be made to the above-described embodiments of the collimated light source, and details are not described herein again. According to the collimated light source, the manufacturing method thereof and the display device provided by the embodiments of the present disclosure, the collimated light source includes a substrate, a film layer with a plurality of concave microstructures located on the substrate, a reflective layer located on the film layer, and a plurality of light-emitting parts corresponding to the concave microstructures one-to-one. Each of the light-emitting parts is located at a focal point of a corresponding concave microstructure. According to the embodiments of the present disclosure, the light emitted from each light-emitting part is reflected by the reflective layer on the corresponding concave microstructure and then exits in parallel light from a side of the reflective layer facing away from the substrate. The collimated light source can be used to provide a collimated backlight for a display panel and a color separation technology can be used to display a color image even when the color film layer is omitted from the display panel, so as to reduce the light energy loss of the display panel and further improve the light extraction efficiency of the liquid crystal display panel. Accordingly, the power consumption of the display panel can also be reduced.

Apparently, the person skilled in the art can make various alterations and variations to the disclosure without departing the spirit and scope of the disclosure. As such, provided that these modifications and variations of the disclosure pertain to the scope of the claims of the disclosure and their equivalents, the disclosure is intended to embrace these alterations and variations.

1. A collimated light source, comprising: a substrate, a film layer with a plurality of concave microstructures located on the substrate, a reflective layer located on the film layer, and a plurality of light-emitting parts corresponding to the concave microstructures one-to-one;
wherein each of the light-emitting parts is located at a focal point of a corresponding concave microstructure.

2. The collimated light source according to claim 1, wherein a surface of each of the concave microstructures is a parabolic surface or a spherical surface.

3. The collimated light source according to claim 2, wherein a depth of each of the concave microstructures ranges from 8 μm to 80 μm and a diameter of each of the concave microstructures ranges from 20 μm to 150 μm.

4. The collimated light source according to claim 1, wherein a material of the film layer with the plurality of concave microstructures is a thermosetting resin.

5. The collimated light source according to claim 2, further comprising a planarization layer located between the reflective layer and the film layer where each of the light-emitting parts is located.

6. The collimated light source according to claim 5, wherein a viscosity of the planarization layer ranges from 0.1×10⁻⁶ mPa·s to 1.5×10⁻⁶ mPa·s.

7. The collimated light source according to claim 5, wherein a refractive index of the planarization layer ranges from 1.5 to 2.

8. The collimated light source according to claim 5, wherein a material of the planarization layer comprises any one of epoxy resin, acrylic resin and polyimide resin.

9. The collimated light source according to claim 1, wherein each of the light-emitting parts is an organic electroluminescent structure, comprising a transparent first electrode, a light-emitting layer and a reflective second electrode sequentially stacked along a direction from the substrate toward the reflective layer.

10. The collimated light source according to claim 9, wherein an area of the light-emitting layer in each of the organic electroluminescent structures ranges from 2 μm² to 15 μm².

11. The collimated light source according to claim 9, wherein an area of the second electrode in each of the organic electroluminescent structures ranges from 4 μm² to 20 μm².

12. The collimated light source according to claim 9, wherein a thickness of the second electrode in each of the organic electroluminescent structures ranges from 100 nm to 500 nm.

13. The collimated light source according to claim 1, wherein a material of the reflective layer includes any one of aluminum, aluminum neodymium alloy and silver.

14. The collimated light source according to claim 13, wherein a thickness of the reflective layer ranges from 100 nm to 500 nm.

15. The collimated light source according to claim 1, wherein the plurality of light-emitting parts are point light sources arranged in an array, and the plurality of concave microstructures are a plurality of recesses arranged in an array; alternatively, wherein the plurality of light-emitting parts are line light sources arranged parallel to each other, and the plurality of concave microstructures are a plurality of grooves arranged parallel to each other.

16. A display device, comprising: a display panel, a backlight module, and a color separation layer between the display panel and the backlight module; wherein the backlight module is the collimated light source according to claim 1.

17. A method for manufacturing a collimated light source, comprising:
forming a film layer with a plurality of concave microstructures on a substrate;
forming a reflective layer on the substrate on which the film layer is formed;
forming a plurality of light-emitting parts corresponding to the concave microstructures one-to-one on the substrate on which the reflective layer is formed; wherein each of the light-emitting parts is located at a focal point of a corresponding concave microstructure.

18. The method according to claim 17, wherein the step of forming a film layer with a plurality of concave microstructures comprises:
forming a film layer on the substrate by using a thermosetting resin material;
forming a plurality of concave microstructures by nano-imprinting the film layer;
heat-treating the film layer on which the plurality of concave microstructures is formed.

19. The method according to claim 18, wherein a heating temperature ranges from 70° C. to 200° C.

20. The method according to claim 17, wherein after the reflective layer is formed and before each of the light-emitting parts is formed, further comprising:
forming a planarization layer on the substrate on which the reflection layer is formed.
